(19) United States
(12) Patent Application Publication
(10) Pub. No.: US 2021/0378155 A1
(43) Pub. Date: Dec. 2, 2021

(54) HEAT DISSIPATION FILM LAYER AND DISPLAY DEVICE HAVING THE SAME

(71) Applicant: WUHAN CHINA STAR OPTOELECTRONICS SEMICONDUCTOR DISPLAY TECHNOLOGY CO., LTD., Wuhan, Hubei (CN)

(72) Inventor: Chuan Qin, Wuhan (CN)

(21) Appl. No.: 16/320,144

(22) PCT Filed: Dec. 20, 2018
(86) PCT No.: PCT/CN2018/122397

§ 371 Date: Jan. 24, 2019

(30) Foreign Application Priority Data
Nov. 13, 2018 (CN) 201811348840.1

(51) Int. Cl. H05K 7/20; G06F 1/20

(52) U.S. Cl. CPC H05K 7/20963; G06F 1/203

(57) ABSTRACT

A heat dissipation film layer and a display device having the heat dissipation film layer are disclosed. The heat dissipation film layer includes a first metal layer, a second metal layer, and a heat storage layer disposed between the first metal layer and the second metal layer. In the designed structure, heat generation of a display and temperature abnormality inside the display device are improved, and service life issues, arising from the display and other components due to excessive temperatures, are overcome. The design provides a proper temperature to increase comfort of holding the display device.

### BACKGROUND OF INVENTION

### 1. Field of Invention

The present invention relates to heat dissipation and heat conduction material technical field, and particularly to a heat dissipation film layer and a display device having the heat dissipation film layer.

### 2. Related Art

With nonstop development of technology, display technology is ever-changing. Display technology based on different principles is widely used in various industries. However, current display technology still inevitably encounters a heat issues arising from emittance of light. Additionally, current display devices are integrated inside with more and more components, and heat generated by some of the components also affects stability of the entire devices, which even gives rise to a certain degree of safety risks.

Please refer to FIGS. 1 and 2. A current display device has a structure as follows: a cover outer plate 110 is disposed on an outermost side of the display device, and a foam layer 130 and a copper (Cu) foil 140 are attached to a backside of a display 120 of the display device to enhance heat dissipation of the display. Heat conductive glue is added to the copper foil 140 and a flexible printed circuit board 122 on the backside of the display 120 to transfer heat, as shown in FIG. 2. In addition, the foam layer 130 is mainly used to enhance buffering and to protect the display. However, the above-mentioned structure has drawbacks as follows: 1) copper foil heat dissipation only allows heat to be conducted; 2) the heat dissipation performance is limited when it comes to high heat generation; 3) as integrated components of display devices become more and more, simple foam plus copper foils cannot fulfill great temperature control.

### SUMMARY OF INVENTION

An object of the present invention is to provide a heat dissipation film layer and a display device having the same capable of improving heat generation of a display and temperature abnormality inside the display device, overcoming a lifespan problem arising from the display and other components due to excessive temperature, and providing a proper temperature to increase comfort of holding the display device.

The present invention provides a heat dissipation film layer, adapted to a display device, the heat dissipation film layer comprising: a first metal layer, a second metal layer, and a heat storage layer disposed between the first metal layer and the second metal layer; the heat storage layer comprising a plurality of sub-areas being square or honeycomb in configuration, and each of the sub-areas filled with a mixed material mixed of a heat storage material and a heat conduction material.

The present invention further provides a heat dissipation film layer, adapted to a display device, the heat dissipation film layer comprising: a first metal layer, a second metal layer, and a heat storage layer disposed between the first metal layer and the second metal layer.

In one embodiment of the present invention, each of the first metal layer and the second metal layer has a thickness less than 40 micrometers (μm).

In one embodiment of the present invention, the heat storage layer has a thickness between 100 μm and 300 μm.

In one embodiment of the present invention, each of the first metal layer and the second metal layer is made of copper, silver, or aluminum.

In one embodiment of the present invention, the heat storage layer comprises a plurality of sub-areas.

In one embodiment of the present invention, the plurality of sub-areas are square in configuration.

In one embodiment of the present invention, the plurality of sub-areas are honeycomb in configuration.

In one embodiment of the present invention, each of the sub-areas is filled with a mixed material of a heat storage material and a heat conduction material.

In one embodiment of the present invention, the heat conduction material has a mass fraction accounting for 5% to 15% of the mixed material.

The present invention further provides a display device, the display device includes a display, and the heat dissipation film layer is disposed on a backside of the display.

In one embodiment of the present invention, a foam layer is disposed between the backside of the display and the heat dissipation film layer, and the foam layer is made of a foam material.

The present invention has advantages as follows: the heat dissipation film layer of the present invention utilizes the heat storage material to absorb heat, with the heat storage material encapsulated to be a film layer to be laminated to the backside of the display, and to control the temperature inside the display device in such a way that heat is absorbed and stored at the time of conducting heat, maintaining the temperature of the entire display device in a predetermined range. In particular to abruptly heating inside the internal of the display device, such as high brightness of a display panel, overload operation of a processor, or an abnormal battery, simple heat dissipation is incapable of dissipating a large amount within a short time. The storage material then is capable of absorbing heat and storing it and slowly releasing it when the ambient temperature drops. In this manner, it ensures the stability of the internal temperature of the display and the display device, thereby ensuring the normal display and lifespan of the display, and also providing protection for internal components of the display device. Additionally, a proper temperature increases comfort of holding the display device.

### BRIEF DESCRIPTION OF DRAWINGS

To describe the technical solutions in the embodiments of the present invention, the following briefly introduces the accompanying drawings for describing the embodiments. Apparently, the accompanying drawings in the following description show merely some embodiments of the present invention, and a person skilled in the art may still derive other drawings from these accompanying drawings without creative efforts.

FIG. 1 is a schematic structural view of a display device of prior art.

FIG. 2 is a schematic view showing a backside configuration of a display of prior art.

FIG. 3 is a schematic structural view of a heat dissipation film layer in accordance with an embodiment of the present invention.

FIG. 4 is a schematic structural view of a display device in accordance with another embodiment of the present invention.

FIG. 5 is a structural side view of a foam layer and a heat dissipation film layer of the embodiment of the present invention.

FIG. 6 is a schematic structural view of the foam layer and the heat dissipation film layer of FIG. 5.

FIG. 7 is a schematic structural view of square sub-areas of the embodiment of the present invention.

FIG. 8 is a schematic structural view of honeycomb sub-areas of the embodiment of the present invention.

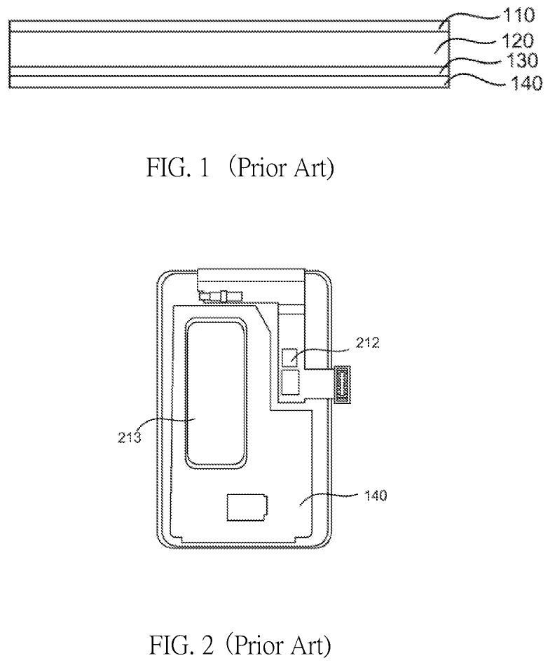

### DESCRIPTION OF PREFERRED EMBODIMENTS

Hereafter, embodiments of the present invention will be described in detail with reference to the accompanying drawings. Apparently, the accompanying embodiments in the following description show merely some, but not all, embodiments of the present invention, and a person skilled in the art based on the embodiments of the present invention may still derive other embodiments from these accompanying embodiments without creative efforts.

The terms “first”, “second”, “third”, etc. (if present) in the specification and claims of the present invention and the above figures are used to distinguish similar objects, and are not necessarily used to describe a specific order or priority. It should be understood that the objects so described are interchangeable where appropriate. Moreover, the terms “comprise” and “has” and any variations thereof are intended to cover a non-exclusive inclusion.

The drawings discussed below and the various embodiments used to describe the principles of the present invention are intended to be illustrative only and not to limit the scope of the invention. Those skilled in the art will appreciate that the principles of the present invention can be implemented in any suitably arranged system. Exemplary embodiments will be described in detail, examples of which are illustrated in the accompanying drawings. Further, a terminal according to an exemplary embodiment will be described in detail with reference to the accompanying drawings. The same reference numerals in the drawings denote the same elements.

The terms used in the description of the present invention are intended to describe a particular embodiment, and are not intended to illustrate the concept of the invention. Expressions used in the singular encompasses the plural form of expression unless the context clearly dictates otherwise. In the description of the present invention, it is to be understood that the terms such as “include”, “have”, and “include” are intended to describe the possibility of one or more other features, numbers, steps, actions, or combinations disclosed in the present invention, and are not intended to exclude the possibility that one or more other features, numbers, steps, acts, or combinations thereof may be added. The same reference numerals in the drawings denote the same parts.

The present invention provides embodiments of a heat dissipation film layer and a display device having the same, which are described in detail hereafter.

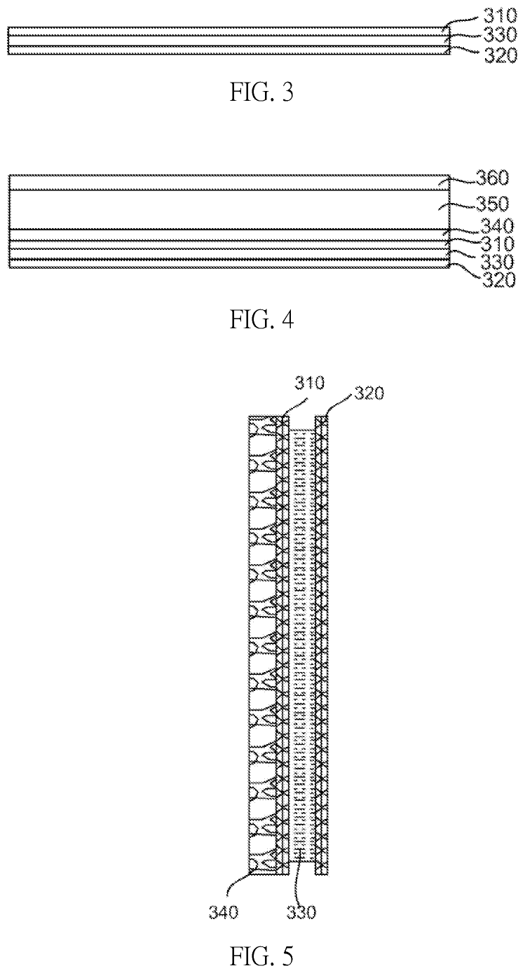

Please refer to FIG. 3. In one embodiment of the present invention, the present invention provides a heat dissipation film layer including a first metal layer 310, a second metal layer 320, and a heat storage layer 330 disposed between the first metal layer 310 and the second metal layer 320. That is, the heat dissipation film layer includes the metal layer 310, the heat storage layer 330, and the second metal layer 320 laminated on each other in turn.

In the present embodiment, each of the first metal layer 310 and the second metal layer 320 is made of copper, which has good thermal conductivity, ductility, and cost performance. Certainly, in other embodiments, both the first metal layer 310 and the second metal layer 320 may be made of silver or aluminum or other metal materials. In comparison with a heat dissipation manner of a conventional copper foil structure, the heat dissipation film layer of the present invention utilizes the first metal layer 310, the heat storage layer 330, and the second metal layer 320 to carry out heat dissipation. In this manner, it is more advantageous for the metal layer of two layers to provide electrostatic protection for display circuits, thereby reducing electromagnetic interference.

The heat storage layer 330 includes a plurality of sub-areas 331. Each of the sub-areas 331 is filled with a mixed material mixed of a heat storage material and a heat conduction material. Certainly, the heat storage 330 can be directly made of the mixed material mixed of the heat storage material and the heat conduction material. The heat conduction material has a mass fraction accounting for 5% to 15% of the mixed material.

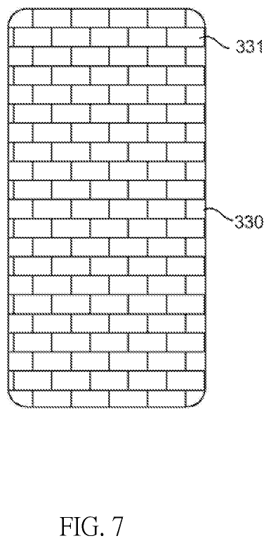

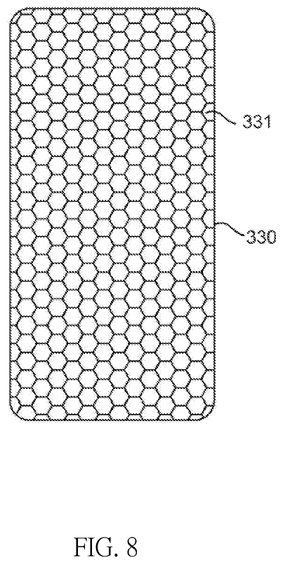

Furthermore, as shown in FIG. 7 and FIG. 8, each of the sub-areas 331 is square or honeycomb in configuration, and therefore the mixed material filled in each of the sub-areas 331 does not interfere with each other.

The heat storage material of the heat storage layer 330 is a phase change material. The phase change material is a substance that changes the state of a substance subject to temperatures and provides latent heat. A process of transforming physical properties is called a phase change process, in which case the phase change material is absorbing or releasing a large amount of latent heat.

The phase change material includes organic materials, molten salts, alloys, and composite phase change materials. The organic materials may be a solid-solid phase change material, such as polyethylene glycol (PEG) or methyl-1,3-propanediol (AMP). The alloy materials can be a lower melting alloy phase change material composed of a metal element, such as Sn, Bi, Pb, Cd, Ga, or Sb. The composite materials can be a paraffin material.

The heat conduction material can be graphene, which has an extremely high thermal conductivity, thus facilitating the dissipation of heat transfer of the heat dissipation film layer. Certainly, in other embodiments, the heat conduction material is not limited thereto.

Therefore, the heat storage layer 330 utilizes the phase change material and graphene to store heat in a format of a phase change latent heat in the phase change material, realizing transformation and utilization in different time and space. When a temperature of the display device rises abnormally, heat is stored in the phase change material through the phase change latent heat; when an outside temperature is relatively low, the phase change material releases heat through a phase change process, thereby maintaining an internal temperature of the display device for not changing too fast.

Furthermore, in this embodiment, both the first metal layer 310 and the second metal layer 320 have a thickness preferably less than 40 micrometers (μm), while a thickness range of the heat storage layer 330 of a small-sized display is recommended to be in a range of 100 μm to 300 μm. However, when a thickness is greater, it can provide better temperature control performance but resulting in an increase of a thickness of the display. In a case that the thickness is not the point, the thickness can be appropriately increased. By a reasonable selection of the first metal layer 310, the second metal layer 320, and the heat storage layer 330, a thickness of the entire display device can be excellently controlled.

The internal temperature of the entire display device is maintained in a predetermined range through a structure of the above-mentioned heat dissipation film layer, thereby not only to ensure a normal operation of the display and other components, but also to mitigate damages on a lifespan and performance of each component, as well as enhance user experience.

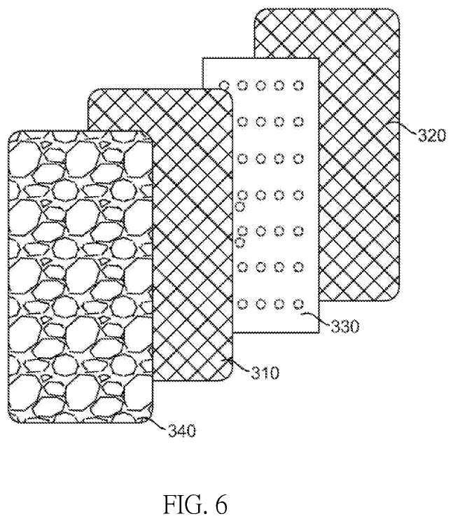

Please refer to FIGS. 4 to 8. The present invention further provides a display device including a display 350, and the heat dissipation film layer is disposed on a backside of the display 350. The specific structure of the heat dissipation film layer includes the metal layer 310, the heat storage layer 330, and the second metal layer 320 laminated on each other in turn. That is, the metal layer 310, the heat storage layer 330, and the second metal layer 320 are directly encapsulated to form a unitary heat dissipation film layer. In this embodiment, each of the first metal layer 310 and the second metal layer 320 is made of copper, which has good thermal conductivity, ductility, and cost performance.

In comparison with a heat dissipation manner of a conventional copper foil structure, the heat dissipation film layer of the present invention utilizes the first metal layer 310, the heat storage layer 330, and the second metal layer 320 to carry out heat dissipation. In this manner, it is more advantageous for the metal layer of two layers to provide electrostatic protection for display circuits, thereby reducing electromagnetic interference.

The heat storage layer 330 includes a plurality of sub-areas 331. Each of the sub-areas 331 is square in configuration. In other embodiments, the sub-areas 331 are honeycomb in configuration. Therefore, the mixed material filled in each of the sub-areas 331 does not interfere with each other. The heat storage layer 330 (i.e. the heat storage material is graphene) is configured in a singular film layer capable of performing heat control and heat transfer. The heat conduction material has a mass fraction accounting for 5% to 15% of the mixed material.

Furthermore, the heat storage material of the heat storage layer 330 is a phase change material. The phase change material includes organic materials, molten salts, alloys, and composite phase change materials. The organic materials may be a solid-solid phase change material, such as polyethylene glycol (PEG) or methyl-1,3-propanediol (AMP). The alloy materials can be a lower melting alloy phase change material composed of a metal element such as Sn, Bi, Pb, Cd, Ga, or Sb. The composite materials can be a paraffin material.

The heat conduction material can be graphene, which has an extremely high thermal conductivity, thus facilitating the dissipation of heat transfer of the heat dissipation film layer.

Therefore, the heat storage layer 330 utilizes the phase change material and graphene to store heat in a format of a phase change latent heat in the phase change material, realizing transformation and utilization in different time and space. When a temperature of the display device rises abnormally, heat is stored in the phase change material through the phase change latent heat; when an outside temperature is relatively low, the phase change material releases heat through a phase change process, thereby maintaining an internal temperature of the display device for not changing too fast.

Furthermore, in this embodiment, both the first metal layer 310 and the second metal layer 320 have a thickness preferably less than 40 micrometers (μm), while a thickness range of the heat storage layer 330 of a small-sized display 350 is recommended to be in a range of 100 μm to 300 μm. However, when a thickness is greater, it can provide better temperature control performance but resulting in an increase of a thickness of the display. In the case that the thickness is not the point, the thickness can be appropriately increased. By a reasonable selection of the first metal layer 310, the second metal layer 320, and the heat storage layer 330, a thickness of the entire display device can be excellently controlled.

Furthermore, a foam layer 340 is disposed between the backside of the display 350 and the heat dissipation film layer, and the foam layer 340 is made of a foam material, thereby to provide further buffering and protection for the display 350.

A cover glass 360 is also disposed on an outer surface of the display 350, and the cover glass 360 also functions to protect the display 350.

The heat dissipation film layer of the present invention utilizes the heat storage material to absorb heat, with the heat storage material encapsulated to be a film layer to be laminated to the backside of the display, and to control the temperature inside the display device in such a way that heat is absorbed and stored at the time of conducting heat, maintaining the temperature of the entire display device in a predetermined range. In particular to abruptly heating inside the internal of the display device, such as high brightness of a display panel, overload operation of a processor, or an abnormal battery, simple heat dissipation is incapable of dissipating a large amount of heat within a short time. The storage material then is capable of absorbing heat, storing it, and slowly releasing it when the ambient temperature drops. In this manner, it ensures the stability of the internal temperature of the display and the display device, thereby ensuring the normal display and the lifespan of the display, and also providing protection for internal components of the display device. Additionally, a proper temperature increases comfort of holding the display device.

The heat dissipation film layer and the display device having the heat dissipation film layer provided by the embodiments of the present invention are described in detail above. It is understood that the exemplary embodiments described herein are to be considered as illustrative only, and are not intended to limit the invention. Descriptions of features or aspects in each exemplary embodiment should generally be considered as suitable features or aspects in other exemplary embodiments. While the invention has been described with reference to the preferred embodiments thereof, various modifications and changes can be made by those skilled in the art. The invention is intended to cover such modifications and modifications within the scope of the appended claims.

The subject matter of the present application is feasible to be manufactured and used in the industry, and thus has the industrial applicability.

1. A heat dissipation film layer, adapted to a display device, the heat dissipation film layer comprising: a first metal layer, a second metal layer, and a heat storage layer disposed between the first metal layer and the second metal layer; the heat storage layer comprising a plurality of sub-areas being square or honeycomb in configuration, and each of the sub-areas filled with a mixed material mixed of a heat storage material and a heat conduction material.

2. A heat dissipation film layer, adapted to a display device, the heat dissipation film layer comprising: a first metal layer, a second metal layer, and a heat storage layer disposed between the first metal layer and the second metal layer.

3. The heat dissipation film layer of claim 2, wherein each of the first metal layer and the second metal layer has a thickness less than 40 micrometers (μm).

4. The heat dissipation film layer of claim 2, wherein the heat storage layer has a thickness between 100 μm and 300 μm.

5. The heat dissipation film layer of claim 2, wherein each of the first metal layer and the second metal layer is made of copper, silver, or aluminum.

6. The heat dissipation film layer of claim 2, wherein the heat storage layer comprises a plurality of sub-areas.

7. The heat dissipation film layer of claim 6, wherein the plurality of sub-areas are square in configuration.

8. The heat dissipation film layer of claim 6, wherein the plurality of sub-areas are honeycomb in configuration.

9. The heat dissipation film layer of claim 6, wherein each of the sub-areas is filled with a mixed material of a heat storage material and a heat conduction material.

10. The heat dissipation film layer of claim 9, wherein a mass fraction of the heat conduction material is 5% to 15% of the mixed material.

11. A display device, comprising a display and the heat dissipation film layer according to claim 1 disposed on a backside of the display.

12. The display device of claim 11, further comprising a foam layer disposed between the backside of the display and the heat dissipation film layer, and the foam layer is made of a foam material.
